(19) United States
(12) Patent Application Publication
(10) Pub. No.: US 2024/0355963 A1
(43) Pub. Date: Oct. 24, 2024

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: Jenlung YANG, Xiamen (CN); Ping ZHANG, Xiamen (CN); Yawen LIN, Xiamen (CN); Shiwang HUANG, Xiamen (CN); Chung-Ying CHANG, Xiamen (CN)

(21) Appl. No.: 18/621,149

(22) Filed: Mar. 29, 2024

(30) Foreign Application Priority Data
Apr. 21, 2023 (CN) 2023104361741

(51) Int. Cl. H01L 33/14

(52) U.S. Cl. CPC H01L 33/145

(57) ABSTRACT

A light-emitting diode and a light-emitting device are provided. The light-emitting diode includes: a semiconductor stacked layer including: a first semiconductor layer, a light-emitting layer and a second semiconductor layer sequentially stacked in that order from a lower surface to an upper surface; a first electrode disposed on the first semiconductor layer; a second electrode; and a first current blocking layer disposed between the first semiconductor layer and the first electrode. When looking down at the semiconductor stacked layer from above the light-emitting diode, a second blocking area of the first current blocking layer is not overlapped with the first electrode, and at least part of the second blocking area is disposed outside an edge of the first electrode proximate to a side of the second electrode. Through a design of the first current blocking layer, light extraction and resistance to electro-static discharge (ESD) impacts are improved.

### TECHNICAL FIELD

The disclosure relates to the field of semiconductor manufacturing technologies, and more particularly to a light-emitting diode and a light-emitting device.

### BACKGROUND

A light-emitting diode is made from a semiconductor such as gallium nitride (GaN), gallium arsenide (GaAs), gallium phosphide (GaP) or gallium arsenide phosphate (GaAsP), and a core of the light-emitting diode is a PN junction with a luminescent property. Under forward voltage, electrons are injected into a positive (P) region from a negative (N) region, holes are injected into the N region from the P region, and a part of minority carriers entering the opposite region combines with majority carriers to emit light. The light-emitting diode has advantages of high light-emitting intensity, high efficiency, small size and long service life, and is considered to be one of the most potential light sources at present.

Currently, a current blocking layer is usually disposed under a P-type electrode to achieve lateral current expansion in existing light-emitting diodes, but the current blocking layer is not disposed under a N-type electrode, even though the current blocking layer is disposed under the N-type electrode, there are still problems such as a low light-emitting utilization rate and poor resistance to electro-static discharge (ESD) impacts.

Therefore, how to improve a light extraction efficiency and the resistance to ESD impacts of the N-type electrode is one of technical problems to be solved urgently.

### SUMMARY

The disclosure provides a light-emitting diode, which solves at least one technical problem in the background, and achieves effective current expansion. In some embodiments, the light-emitting diode at least includes: a semiconductor stacked layer, a first electrode, a second electrode and a first current blocking layer.

The semiconductor stacked layer has lower and upper surfaces opposite to each other, and includes: a first semiconductor layer, a light-emitting layer and a second semiconductor layer sequentially stacked in that order from the lower surface to the upper surface.

The first electrode is disposed on the first semiconductor layer, and is electrically connected to the first semiconductor layer.

The second electrode is disposed on the second semiconductor layer, and is electrically connected to the second semiconductor layer.

The first current blocking layer is disposed between the first semiconductor layer and the first electrode.

The first current blocking layer includes: a first blocking area and a second blocking area; the first blocking area overlaps with the first electrode, and the second blocking area does not overlap with the first electrode as viewed in a direction from above the light-emitting diode towards the semiconductor stacked layer; and at least part of the second blocking area is disposed outside an edge of the first electrode proximate to a side of the second electrode.

The disclosure further provides a light-emitting device, and the light-emitting device includes: the light-emitting diode as described in the above embodiment.

The light-emitting diode provided by the disclosure designs a pattern of the first current blocking layer under the first electrode, so as to effectively improve phenomena of uneven distribution of electric field intensity and current accumulation, and improve a light extraction ability and resistance to ESD impacts of the light-emitting diode.

Other features and beneficial effects of the disclosure will be described in the subsequent specification, and in part will be obvious from the description, or may be learned by practice of the disclosure.

### BRIEF DESCRIPTION OF DRAWINGS

In order to provide a clearer explanation of technical solutions in embodiments of the disclosure or related art, drawings required in the embodiments or the related art descriptions will be simply introduced below. Apparently, the drawings in the descriptions are some of the embodiments, for those skilled in the art, other drawings can be obtained according to the drawings without creative work.

FIG. 1 illustrates a schematic diagram from a top-down perspective of a light-emitting diode in the related art.

FIG. 2 illustrates a light-emitting intensity distribution diagram of the light-emitting diode illustrated in FIG. 1 in the related art.

FIG. 3 illustrates a schematic diagram from a top-down perspective of another light-emitting diode in the related art.

FIG. 4 illustrates a light-emitting intensity distribution diagram of the light-emitting diode illustrated in FIG. 3 in the related art.

FIG. 5 illustrates a schematic sectional diagram from a side perspective of a light-emitting diode with a forward-installed structure according to an embodiment of the disclosure.

FIG. 6 illustrates a schematic sectional diagram from a side perspective of a light-emitting diode with a flip structure according to an embodiment of the disclosure.

FIGS. 7-10 illustrate schematic sectional diagrams from the top-down perspective of the light-emitting diodes according to the embodiments of the disclosure.

FIG. 11 illustrates a light-emitting intensity distribution diagram of the light-emitting diode illustrated in FIG. 10.

FIG. 12 illustrates a line chart of brightness of the light-emitting diodes illustrated in FIG. 1, FIG. 3, FIG. 8, FIG. 9 and FIG. 10.

FIG. 13 illustrates a schematic structural diagram of a light-emitting diode with high voltage structure according to an embodiment of the disclosure.

### LIST OF REFERENCE NUMBERS

10-semiconductor stacked layer; 11-first semiconductor layer; 12-light-emitting layer; 13-second semiconductor layer; 20-first electrode; 30-second electrode; 20a-non-overlapping electrode area; 40-first current blocking layer; 41-first blocking area; 42-second blocking area; S1-shortest distance; S2-minimum distance; 50-insulation layer; 60-substrate; 70-transparent current expansion layer; 80-second current blocking layer; 91-interconnected electrode; 92-third current blocking layer.

### DETAILED DESCRIPTION OF EMBODIMENTS

In order to make purposes, technical solutions and advantages of embodiments of the disclosure clearer, the technical solutions of the embodiments of the disclosure will be clearly and completely described in conjunction with drawings in the embodiments of the disclosure below. Technical features designed in different embodiments of the disclosure described below can be combined with each other as long as they do not conflict with each other.

The disclosure provides a light-emitting diode, and the light-emitting diode at least includes: a semiconductor stacked layer 10, a first electrode 20, a second electrode 30 and a first current blocking layer 40.

Specifically, the semiconductor stacked layer 10 has opposite lower and upper surfaces, and includes: a first semiconductor layer 11, a light-emitting layer 12 and a second semiconductor layer 13 sequentially stacked in that order from the lower surface to the upper surface. The first electrode 20 is disposed on the first semiconductor layer 11, and is electrically connected to the first semiconductor layer 11. The second electrode 30 is disposed on the second semiconductor layer 13, and is electrically connected to the second semiconductor layer 13. The first current blocking layer 40 is disposed between the first semiconductor layer 11 and the first electrode 20.

The first current blocking layer 40 includes: a first blocking area 41 and a second blocking area 42. The first blocking area 41 overlaps with the first electrode 20, and the second blocking area 42 does not overlap with the first electrode 20 as viewed in a direction from above the light-emitting diode towards the semiconductor stacked layer 10. At least part of the second blocking area 42 is disposed outside an edge of the first electrode 20 proximate to a side of the second electrode 30.

The first blocking area 41 and the second blocking area 42 of the first current blocking layer 40 are disposed to suppress current accumulation between the second electrode 30 and the first electrode 20, achieve current expansion while effectively improving phenomena of uneven distribution of electric field intensity and the current accumulation, and improve a light extraction ability and resistance to ESD impacts of the light-emitting diode.

In an embodiment, a shortest distance S1 is defined between the edge of the first electrode 20 and an edge of the second electrode 30, and at least part of the second blocking area 42 is located between the edge of the first electrode 20 and the edge of the second electrode 30 with the shortest distance S1, so that a current path is further extended, and current accumulation in the shortest distance S1 is effectively avoided.

In an embodiment, the first electrode 20 completely or partially overlaps with the first blocking area 41 as viewed in a direction from above the light-emitting diode towards the semiconductor stacked layer 10, so as to provide a good current blocking effect.

In an embodiment, the first electrode 20 partially overlaps with the first blocking area 41 as viewed in a direction from above the light-emitting diode towards the semiconductor stacked layer 10, and a projection area of the first blocking area 41 on the first semiconductor layer 11 accounts for 5% to 96% of a projection area of the first electrode 20 on the first semiconductor layer 11. A problem of a poor current blocking effect caused by a less projection area of the first blocking area 41 is avoided while avoiding a problem of a poor current conductivity caused by a large projection area of the first blocking area 41.

In an embodiment, the first electrode 20 partially overlaps with the first blocking area 41 as viewed in a direction from above the light-emitting diode towards the semiconductor stacked layer 10, and the projection area of the first blocking area 41 on the first semiconductor layer 11 accounts for 50% to 96% of a projection area of the first electrode 20 on the first semiconductor layer 11, so that the first blocking area 41 has a good current blocking effect and a chip has a suitable current conductivity. In addition, the proportion of the first blocking area 41 is set above 50%, which can ensure a larger contact area for current blocking (CB), so as to be beneficial to light-emitting effect of the whole light-emitting diode.

In an embodiment, the first electrode 20 partially overlaps with the first blocking area 41 as viewed in a direction from above the light-emitting diode towards the semiconductor stacked layer 10, and the projection area of the first blocking area 41 on the first semiconductor layer 11 accounts for 10% to 95% of a projection area of the first current blocking layer 40 on the first semiconductor layer 11, so as to provide a good current blocking effect between the first blocking area 41 and the second blocking area 42.

In an embodiment, the first electrode 20 partially overlaps with the first blocking area 41 as viewed in a direction from above the light-emitting diode towards the semiconductor stacked layer 10, and the projection area of the first blocking area 41 on the first semiconductor layer 11 accounts for 40% to 80% of the projection area of the first current blocking layer 40 on the first semiconductor layer 11, so as to further provide a good current blocking effect between the first blocking area 41 and the second blocking area 42.

In an embodiment, at least part of the first blocking area 41 is disposed inside the edge of the first electrode 20 proximate to the second electrode 30 as viewed in a direction from above the light-emitting diode towards the semiconductor stacked layer 10, so that the current further expands to a periphery away from the first blocking area 41, so as to achieve regulation of the electric field intensity, and improve the resistance to ESD impacts of the light-emitting diode.

In an embodiment, the first blocking area 41 partially overlaps with the first electrode 20, the first electrode 20 includes: a non-overlapping electrode area 20a not overlapping with the first blocking area 41, and at least part of the non-overlapping electrode area 20a is disposed inside an edge of the first electrode 20 facing away from the second electrode 30. Through the above design, it is not only beneficial to further extend the current path, increase a current conduction distance, avoid current accumulation between the first electrode 20 and the second electrode 30, but also ensure a good CB contact.

In an embodiment, a projection area of the non-overlapping electrode area 20a on the first semiconductor layer 11 accounts for 4% to 95% of the projection area of the first electrode 20 on the first semiconductor layer 11, so as to ensure that the first electrode 20 not only has a certain current conductivity on the non-overlapping electrode area 20a, but also effectively exerts a current expansion ability on the first blocking area 41. That is, both current conduction and current expansion are considered at the same time, so as to ensure that the light-emitting diode has a better light-emitting effect.

In an embodiment, the first blocking area 41 and the second blocking area 42 extend to cover all edge areas of the first electrode 20 beyond the non-overlapping electrode area 20a, so as to maximum the current expansion, promote the current to spread and distribute around the first electrode 20, and make the whole light-emitting diode have a better light-emitting effect.

In an embodiment, the semiconductor stacked layer 10 defines a mesa exposing a part of an upper surface of the first semiconductor layer 11, the first electrode 20 is disposed on the mesa, and a projection of the second blocking area 42 on the mesa is located inside the mesa. Through the above setting, it is not only beneficial to a manufacturing process of the first current blocking layer 40, but also effectively avoids a risk of micro-leakage caused by a contact between the first current blocking layer 40 and the light-emitting layer 12 when the first current blocking layer 40 has a film defect.

In an embodiment, a minimum distance S2 is defined between the projection of the second blocking area 42 on the mesa and an edge of the mesa, and the minimum distance S2 is larger than or equal to 1 micron (μm), which is beneficial for the manufacturing process of the first current blocking layer 40.

In an embodiment, a distance between the second blocking area 42 and the edge of the first electrode 20 is larger than or equal to 1 μm as viewed in a direction from above the light-emitting diode towards the semiconductor stacked layer 10, so as to ensure an effective current blocking effect of the second blocking area 42.

In an embodiment, the first current blocking layer 40 is in an annular shape, and an inner ring of the annular shape is located inside the first electrode 20 as viewed in a direction from above the light-emitting diode towards the semiconductor stacked layer 10. Through the above design, a good current conduction is achieved while effective reducing a light absorption effect of the first electrode 20.

In an embodiment, a pattern of the first current blocking layer 40 is consistent with that of the first electrode 20, and the pattern of the first current blocking layer 40 is offset towards a direction proximate to the second electrode 30 as viewed in a direction from above the light-emitting diode towards the semiconductor stacked layer 10, so as to achieve an effective regulation effect for the current path, further optimize an electric field intensity distribution, and improve the light extraction ability of the light-emitting diode.

In an embodiment, a material of the first current blocking layer 40 is an insulating material that at least partially transmits light, and the material of the first current blocking layer 40 is at least one selected from the group consisting of silicon oxide, titanium oxide, silicon nitride, aluminum oxide, magnesium fluoride, spin-on glass (SOG, which refers to a silicon material on glass) and polymer, which provides the current blocking effect and an effect of effectively maintaining light-emitting brightness. A thickness of the first current blocking layer 40 is in a range of 50 to 500 nanometers (nm), which can ensure effective current blocking effect and avoid wasting materials.

In an embodiment, the first electrode 20 and the second electrode 30 are made of a metal material, and the mental material includes at least one selected from the group consisting of nickel, gold, chromium, titanium, platinum, palladium, rhodium, iridium, aluminum, tin, indium, tantalum, copper, cobalt, iron, ruthenium, zirconium, tungsten and molybdenum, or the metal material includes at least one selected from the group consisting of alloys or stacks of the above materials, which are used to achieve electrically connection of the first electrode 20 and the second electrode 30.

The disclosure further provides a light-emitting device, and the light-emitting device includes: the light-emitting diode as described in the above embodiment, so as to effectively improve performance of the light-emitting device.

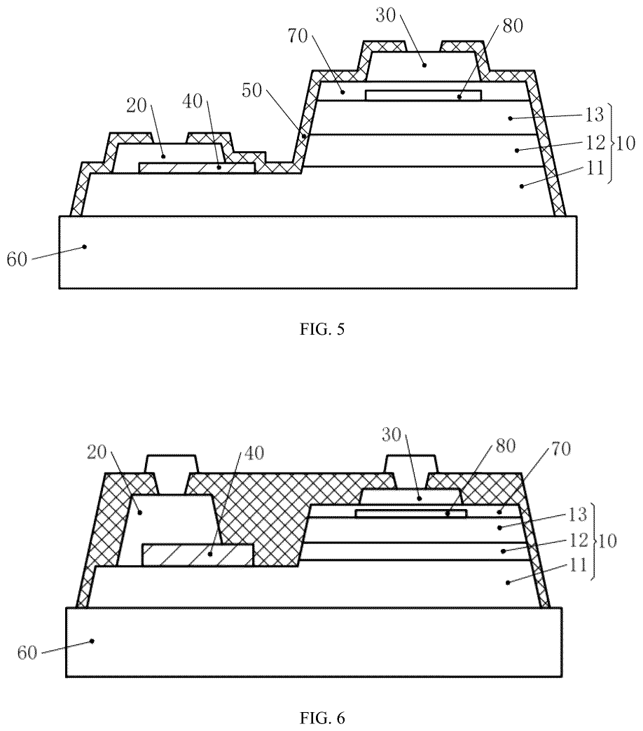

The technical solutions of the disclosure will be clearly and completely described through various specific implementation methods in conjunction with the drawings in the embodiments of the disclosure. Please refer to FIGS. 5 and 6, FIG. 5 illustrates a schematic sectional diagram from a side perspective of a light-emitting diode with a forward-installed structure (i.e., wire bonding) according to an embodiment of the disclosure, and FIG. 6 illustrates a schematic sectional diagram from a side perspective of a light-emitting diode with a flip structure (i.e., flip chip bonding) according to an embodiment of the disclosure. In order to achieve at least one of the advantages or other advantages, an embodiment of the disclosure provides a light-emitting diode, and the light-emitting diode at least includes: a semiconductor stacked layers 10, a first electrode 20, a second electrode 30 and a first current blocking layer 40.

The semiconductor stacked layer 10 is disposed on a substrate 60. The substrate 60 can be a transparent substrate, a non-transparent substrate, or a semi-transparent substrate. The transparent substrate or the semi-transparent substrate can allow light emitted by a light-emitting layer 12 to pass through the substrate 60 and reach a side of the substrate 60 facing away from the semiconductor stacked layer 10. For example, the substrate 60 can be at least one selected from the group consisting of a sapphire flat substrate, a sapphire patterned substrate, a silicon substrate, a silicon carbide substrate, a gallium nitride substrate and a glass substrate. In some embodiment, the substrate 60 can adopt a combined patterned substrate. In other embodiments, the substrate 60 can be thinned or removed to form a thin film chip.

The semiconductor stacked layer 10 has lower and upper surfaces opposite to each other, and includes: a first semiconductor layer 11, a light-emitting layer 12 and a second semiconductor layer 13 sequentially stacked in that order from the lower surface to the upper surface. Specifically, the first semiconductor layer 11 is disposed on the substrate 60, and as a layer grown on the substrate 60, the first semiconductor layer 11 can be a layer doped with N-type impurity such as a gallium nitride semiconductor layer of silicon (Si). In some embodiments, a buffer layer can be also disposed between the first semiconductor layer 11 and the substrate 60. In other embodiments, the first semiconductor layer 11 can be connected to the substrate 60 through an adhesive layer.

The light-emitting layer 12 can be a quantum well (QW) structure. In some embodiments, the light-emitting layer 12 can also be a multiple quantum well (MQW) structure. Specifically, the MQW structure includes: multiple quantum well layers and multiple quantum barrier layers alternately arranged in a repetitive manner. In addition, a wavelength of generated light is determined by a composition and a thickness of the well layers in the light-emitting layer 12. Especially, the light-emitting layer 12 generating different color light such as ultraviolet, blue light, green light and yellow light is provided by adjusting the composition of the well layers.

The second semiconductor layer 13 can be a layer doped with P-type impurity such as a gallium nitride semiconductor layer of magnesium (Mg). The first semiconductor layer 11 and the second semiconductor layer 13 can be single-layer structures, however, the disclosure is not limited to this, the first semiconductor layer 11 and the second semiconductor layer 13 can be multilayers, also include superlattice layers. Furthermore, in other embodiments, in a situation that the first semiconductor layer 11 is the layer doped with P-type impurity, the second semiconductor layer 13 can be the layer doped with N-type impurity, that is, the first semiconductor layer 11 is a P-type semiconductor layer, and the second semiconductor layer 13 is a N-type semiconductor layer.

Obviously, the semiconductor stacked layer 10 can include other layer materials, such as a window layer or an ohmic contact layer, and the other layer materials can be designed as different multilayers according to different doped concentrations and component contents.

In an embodiment, the first electrode 20 is disposed on the first semiconductor layer 11 and is electrically connected to the first semiconductor layer 11. The second electrode 30 is disposed on the second semiconductor layer 13 and is electrically connected to the second semiconductor layer 13.

In the embodiment, the first electrode 20 and the second electrode 30 can be metal electrodes, that is, the first electrode 20 and the second electrode 30 can be made of a metal material, and the metal material is at least one selected from the group consisting of nickel, gold, chromium, titanium, platinum, palladium, rhodium, iridium, aluminum, tin, indium, tantalum, copper, cobalt, iron, ruthenium, zirconium, tungsten and molybdenum, or the metal material is an alloy or a stated layer made of at least one of the above materials. As an example, the first electrode 20 can be a N electrode, and the second electrode 30 can be a P electrode.

In some embodiment, please continue to refer to FIG. 5, a transparent current expansion layer 70 and/or a second current blocking layer 80 can be disposed below the second electrode 30, and the second current blocking layer 80 is disposed between the semiconductor stacked layer 10 and the transparent current expansion layer 70. The second electrode 30 is in contact with the second current blocking layer 80 in up and down correspondence, that is, a projection of the second electrode 30 on the second current blocking layer 80 is located inside the second current blocking layer 80. The second current blocking layer 80 is used to block the current, and avoid the current from crowding directly below the second electrode 30 to make the current spread. The transparent current expansion layer 70 is used as a channel for current flow, so that the current flows a whole surface of the second semiconductor layer 13 through the transparent current expansion layer 70, so as to avoid current crowding, ensure that the current spreads as far as possible across the surface of the second semiconductor layer 13, and improve light-emitting efficiency. As an example, the second current blocking layer 80 can be silicon oxide (SiO₂), silicon nitride (Si₃N₄), silicon oxynitride (SiON) or their composite structures. The transparent current expansion layer 70 can include at least one selected from the group consisting of indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO) and gallium doped zinc oxide (GZO). In the embodiment, the transparent current expansion layer 70 is an ITO (i.e., an indium tin oxide semiconductor transparent conductive film) layer prepared by using an evaporation or a sputtering process.

In an embodiment, the light-emitting diode can further include an insulation layer 50, the insulation layer 50 covers the semiconductor stacked layer 10, and can also cover a part of the first electrode 20 and a part of the second electrode 30. The insulation layer 50 has different functions according to designed positions, for example: when the insulation layer 50 covers a side wall of the semiconductor stacked layer 10, the insulation layer 50 can be used to prevent electrical connection between the first semiconductor layer 11 and the second semiconductor layer 13 due to leakage of a conductive material, and reduce a possibility of short circuit anomalies in the light-emitting diode, however, the embodiments of the disclosure are not limited to this. A material of the insulation layer 50 includes a non-conductive material. The non-conductive material is an inorganic material or a dielectric material. The inorganic material can include silica gel. The dielectric material includes: aluminum oxide, silicon nitride, silicon oxide, titanium oxide, magnesium fluoride and other electric insulation materials. For example: the insulation layer 50 can be silicon oxide, silicon nitride, titanium oxide, tantalum oxide, niobium oxide, barium titanate or a combination thereof, and the combination can be a bragg reflector (DBR) formed by repeated stacking of two materials with different refractive indices.

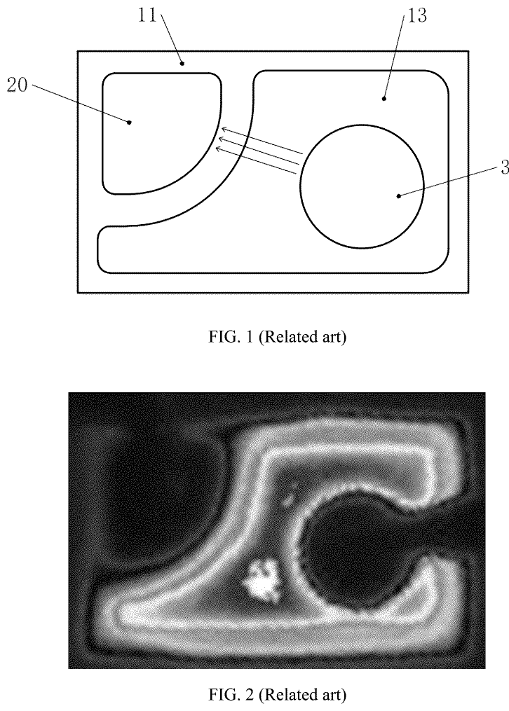

Please refer to FIG. 1, FIG. 1 illustrates a light-emitting diode in the related art, and a current blocking layer is generally disposed below the second electrode 30 of the light-emitting diode to suppress current accumulation near the second electrode 30 of the chip. The current blocking layer is not generally disposed below the first electrode 20 of the light-emitting diode, which causes a problem that the first electrode 20 made of a metal material has a large light absorption and shielding, resulting in a low light extraction efficiency of the light-emitting diode. FIG. 2 illustrates a light-emitting intensity distribution diagram of the light-emitting diode illustrated in FIG. 1 in the related art, and a white exposure position in a middle of the second semiconductor layer 13 represents an area where heat is relatively concentrated. An uneven current density distribution (especially the white exposure position shows a current accumulation phenomenon) of the light-emitting diode in FIG. 1 can be predicted through the light-emitting intensity distribution diagram, thereby causing an uneven distribution of an optical radiation power.

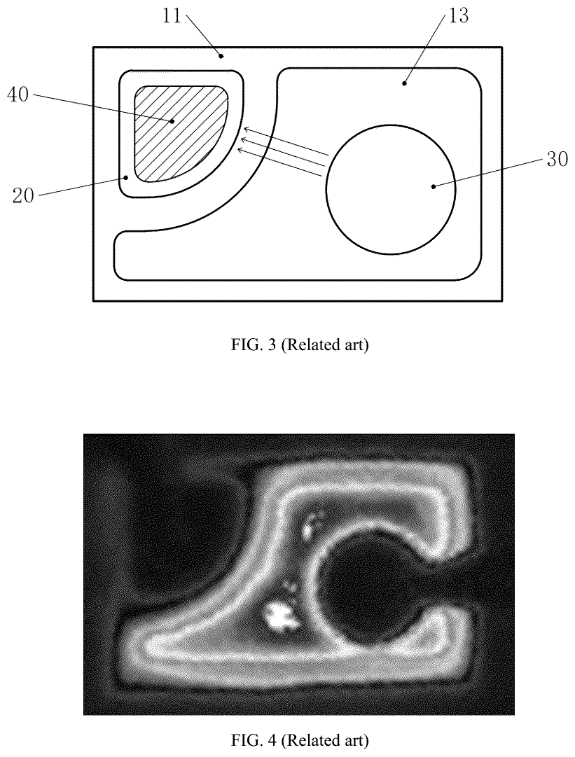

Please refer to FIG. 3, FIG. 3 illustrates another light-emitting diode in the related art, the current blocking layer is disposed below the first electrode 20 of the light-emitting diode, however, this design method is obtained by shrinking a pattern of the electrode according to a certain size, that is, the current blocking layer is disposed inside the first electrode 20. Although the design can improve the light extraction efficiency to a certain extent, the design method of the current blocking layer still has problems of an accumulated and uneven electric field distribution located on a N-type electrode position, a poor light-emitting utilization rate caused by current accumulation, and poor resistance to ESD impacts. As shown in FIG. 4, FIG. 4 illustrates a light-emitting intensity distribution diagram of the light-emitting diode illustrated in FIG. 3 in the related art, and an uneven distribution current density of the light-emitting diode in FIG. 3 can be predicted through the light-emitting intensity distribution diagram, thereby causing the poor light-emitting utilization rate and the poor resistance to ESD impacts.

At least one of the problems mentioned above is overcome through designing the current blocking layer in the embodiment.

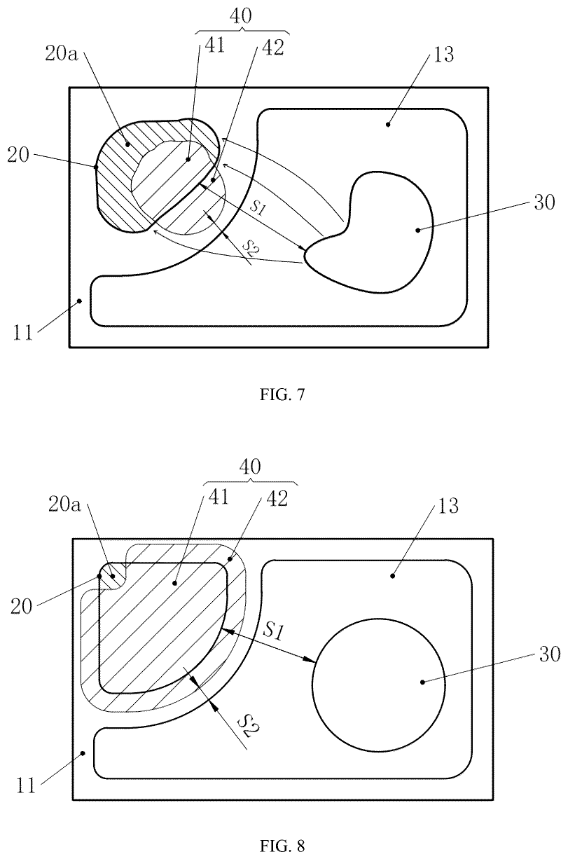

Please continue to refer to FIG. 5 and FIG. 6, a first current blocking layer 40 is disposed between the first semiconductor layer 11 and the first electrode 20. The first electrode 20 corresponds to the first current blocking layer 40. Specifically, please refer to FIGS. 7-10, the first current blocking layer 40 includes: a first blocking area 41 and a second blocking area 42; the first blocking area 41 overlaps with the first electrode 20 and the second blocking area 42 does not overlaps with the first electrode 20 as viewed in a direction from above the light-emitting diode towards the semiconductor stacked layer 10. At least part of the second blocking area 42 is disposed outside an edge of the first electrode 20 proximate to a side of the second electrode 30.

Through designing the first blocking area 41 and the second blocking area 42 in the first current blocking layer 40, an absorption of light by the first electrode 20 is effectively reduced, and the light extraction efficiency of the light-emitting diode is improved.

The current path forms between the second electrode 30 and the first electrode 20 during transmission of injected current from the second electrode 30 to the first electrode 20, specifically, the light-emitting diode in the related art as shown in FIG. 1 and FIG. 3 (arrows indicate current paths formed by flow directions of the current), the current path is prone to causing current accumulation between the second electrode 30 and the first electrode 20, making it difficult to uniformly expand towards surrounding area, resulting in uneven current density distribution and a formation of uneven light-emitting intensity as shown in FIG. 2 and FIG. 4.

In order to solve the above problems, in the embodiment, at least part of the second blocking area 42 is disposed outside the edge of the first electrode 20 proximate to the side of the second electrode 30, which can suppress the current accumulation between the second electrode 30 and the first electrode 20, so as to effectively change the current path. Specifically, as shown in FIG. 7 (arrows indicate the current paths formed by flow directions of the current), the current path expands in a direction of avoiding the second blocking area 42, so as to make the electric field intensity distribution of the whole light-emitting diode more even, improve the light-emitting utilization rate, and improve the resistance to ESD impacts.

As an example, a material of the first current blocking layer 40 is an insulation material, which can be an oxide, and the first current blocking layer 40 can be a relatively transparent material, which allows at least part of radiation from the light-emitting layer 12 to pass through. For example: the material of the first current blocking layer 40 is at least one selected from the group consisting of silicon oxide, titanium oxide, silicon nitride, aluminum oxide, magnesium fluoride, spin-on glass (SOG) and polymer, and the disclosure is not limited to the examples listed here. In an embodiment, a thickness of the first current blocking layer 40 is in a range of 50 to 500 nanometers (nm).

In an embodiment, a shortest distance S1 is defined between the edge of the first electrode 20 and an edge of the second electrode 30, and at least part of the second blocking area 42 is located between the edge of the first electrode 20 and the edge of the second electrode 30 with the shortest distance S1. Through the above setting, a shortest distance of the current path is effectively extended, current accumulation in the shortest distance S1 is effectively avoided, to make the current expand around, so as to avoid inability to achieve good light-emitting in a lower and left corner of the light-emitting area as shown in FIG. 2 and FIG. 4 due to the light-emitting area distance from the current path (i.e., the light-emitting intensity is weak), and further improve uniformity of the electric field intensity of the whole light-emitting diode and the light-emitting utilization rate of the surface.

In an embodiment, the first electrode 20 completely or partially overlaps with the first blocking area 41 as viewed in a direction from above the light-emitting diode towards the semiconductor stacked layer 10. That is, the first electrode 20 can be completely covered by the first blocking area 41, and can be also partially covered by the first blocking area 41, specific settings are made according to actual needs, and there is no limitation here. In an embodiment, in order to ensure the current conductivity, a current expansion layer is disposed between the first electrode 20 and the first semiconductor layer 11 when the first electrode 20 is completely covered by the first blocking area 41, and the current expansion layer covers at least part of the first current blocking layer 40, to thereby achieve conduction and spread of the current. Specifically, a material of the current expansion layer can refer to the aforementioned content of the transparent current expansion layer 70, and not repeated herein.

In addition, the first blocking area 41 can be composed of a single block structure, and can be also composed of multiple disconnected block structures, and at least one block structure is connected to the second blocking area 42 to provide a good current blocking effect. A shape of the first blocking area 41 can be designed into any regular or irregular structure according to actual manufacturing process requirements, without limitation here.

In an embodiment, at least part of the first blocking area 41 is disposed inside the edge of the first electrode 20 proximate to the second electrode 30 as viewed in a direction from above the light-emitting diode towards the semiconductor stacked layer 10. The first blocking area 41 is disposed inside the first electrode 20 proximate to the second electrode 30, so that the current further expands to a periphery facing away from the first blocking area 41, so as to achieve regulation of the electric field intensity, and improve the resistance to ESD impacts of the light-emitting diode.

In an embodiment, the first electrode 20 partially overlaps with the first blocking area 41 as viewed in a direction from above the light-emitting diode towards the semiconductor stacked layer 10, and a projection area of the first blocking area 41 on the first semiconductor layer 11 accounts for 5% to 96% of a projection area of the first electrode 20 on the first semiconductor layer 11. Through the above limitation of the first blocking area 41, a problem of a poor current blocking effect caused by less projection area of the first blocking area 41 is avoided while avoiding a problem of a poor current conductivity caused by a large projection area of the first blocking area 41. Specifically, the projection area of the first blocking area 41 on the first semiconductor layer 11 accounts for 50% to 96% of the projection area of the first electrode 20 on the first semiconductor layer 11. A proportion of the first blocking area 41 is set over 50%, which can effectively ensure a current blocking (CB) contact effect between the first blocking area 41 and the first electrode 20, and effectively improve a whole light-emitting brightness of the light-emitting diode.

In an embodiment, the first electrode 20 partially overlaps with the first blocking area 41 as viewed in a direction from above the light-emitting diode towards the semiconductor stacked layer 10, and the projection area of the first blocking area 41 on the first semiconductor layer 11 accounts for 10% to 95% of a projection area of the first current blocking layer 40 on the first semiconductor layer 11. Specifically, the projection area of the first blocking area 41 on the first semiconductor layer 11 accounts for 40% to 80% of the projection area of the first current blocking layer 40 on the first semiconductor layer 11. Through the above limitations, a good current blocking effect is achieved between the first blocking area 41 and the second blocking area 42.

As another embodiment, the first blocking area 41 partially overlaps with the first electrode 20, the first electrode 20 includes: a non-overlapping electrode area 20a not overlapping with the first blocking area 41, and at least part of the non-overlapping electrode area 20a is disposed inside an edge of the first electrode 20 facing away from the second electrode 30. At least part of the non-overlapping electrode area 20a is disposed inside the first electrode 20 facing away from the second electrode 30, so that a position of the first electrode 20 facing away from the second electrode 30 does not cover the first current blocking layer 40. As shown in FIG. 7 and FIG. 8, the non-overlapping electrode area 20a is located on a left and up corner facing away from the second electrode 30. Through the above settings, the current path is further extended, a current conduction distance is increased, so as to avoid the current accumulation between the second electrode 30 and the first electrode 20 to achieve a local current regulation effect, obtain more even current expansion of the whole light-emitting diode, and ensure a good CB contact.

In an embodiment, a projection area of the non-overlapping electrode area 20a on the first semiconductor layer 11 accounts for 4% to 95% of the projection area of the first electrode 20 on the first semiconductor layer 11. Specifically, the projection area of the non-overlapping electrode area 20a on the first semiconductor layer 11 is larger than or equal to 4% to 50% of the projection area of the first electrode 20 on the first semiconductor layer 11. Through the above limitations, it ensures that the first electrode 20 not only has a certain current conduction ability at the position of the non-overlapping electrode area 20a, but also effectively exserts the current expansion ability at the first blocking area 41, and at the same time, both current conduction and current expansion are considered to ensure that the light-emitting diode has a better light-emitting effect.

In an embodiment, the semiconductor stacked layer 10 defines a mesa exposing a part of an upper surface of the first semiconductor layer 11, the first electrode 20 is disposed on the mesa, and a projection of the second blocking area 42 on the mesa is located inside the mesa. Through the above settings, it is not only beneficial for the manufacturing process of the first current blocking layer 40, but also effectively avoids the risk of micro-leakage when the first current blocking layer 40 is in contact with the light-emitting layer 12 due to film defects.

In an embodiment, a minimum distance is defined between the projection of the second blocking area 42 on the mesa and an edge of the mesa, and the minimum distance is larger than or equal to 1 μm, which is beneficial for the manufacturing process of the first current blocking layer 40. In addition, a distance between the second blocking area 42 and the edge of the first electrode 20 is larger than or equal to 1 μm as viewed in a direction from above the light-emitting diode towards the semiconductor stacked layer 10, so as to ensure an effective current blocking effect of the second blocking area 42. Specifically, the distance between the second blocking area 42 and the edge of the first electrode 20 is in a range of 3-8 μm.

In an optional embodiment, please refer to FIG. 8, in order to provide a best current blocking effect, the first blocking area 41 and the second blocking area 42 extend to cover all edge areas of the first electrode 20 beyond the non-overlapping electrode area 20a, so as to maximum the current expansion, promote the current to spread and distribute around the first electrode 20, and make the whole light-emitting diode have a better light-emitting effect.

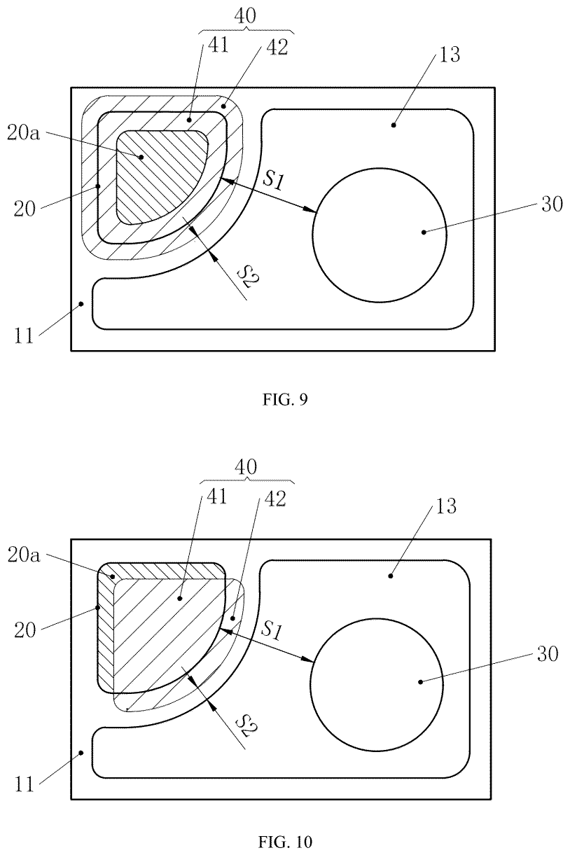

In another optimal embodiment, please refer to FIG. 9, the first current blocking layer 40 is in an annular shape, and an inner ring of the annular shape is located inside the first electrode 20 as viewed in a direction from above the light-emitting diode towards the semiconductor stacked layer 10. In other words, the annular shape of the first current blocking layer 40 covers the edge of the first electrode 20 to reduce a light absorption of the first electrode 20, and a hollow inner ring in a middle of the first current blocking layer 40 does not cover the first electrode 20 to achieve a better current conduction, and decrease an operation voltage of the light-emitting diode.

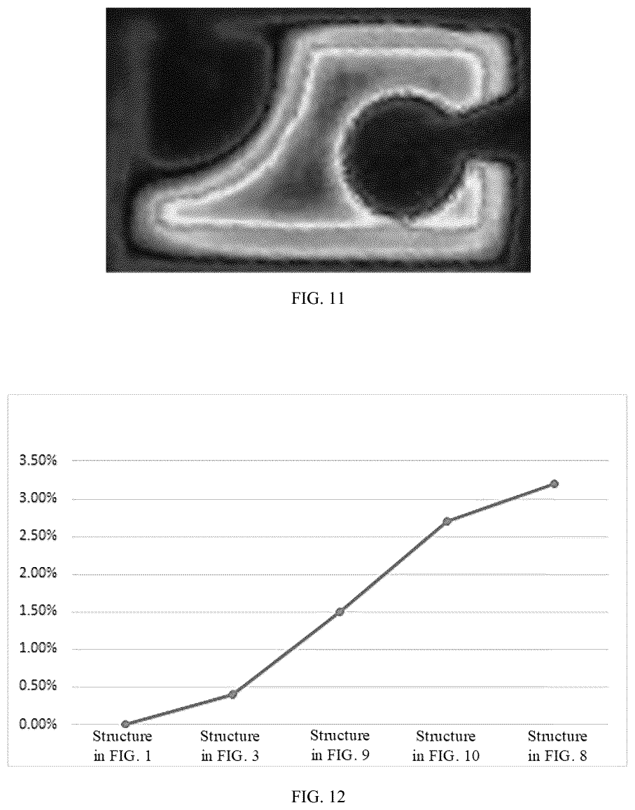

In an alternative embodiment, please refer to FIG. 10, a pattern of the first current blocking layer 40 is consistent with (i.e., the same as) that of the first electrode 20, and the pattern of the first current blocking layer 40 is offset towards a direction proximate to the second electrode 30 as viewed in a direction from above the light-emitting diode towards the semiconductor stacked layer 10. That is, the second blocking area 42 proximate to the second electrode 30, the first blocking area 41 overlapping with the first electrode 20 and the non-overlapping electrode area 20a facing away from the second electrode 30 are constituted after the pattern of the first current blocking layer is offset towards the direction proximate to the second electrode 30. As shown in FIG. 11, FIG. 11 illustrates a light-emitting intensity distribution diagram of the first current blocking layer 40 of the light-emitting diode illustrated in FIG. 10, and it can be seen from that the light-emitting intensity of the whole light-emitting surface is more even. Therefore, this design can achieve a regulation effect for the current path, thereby optimizing the electric field intensity distribution, and improving the light extraction ability. The embodiment only takes FIG. 10 as an example to make the light-emitting intensity distribution diagram, and the light-emitting diodes in other embodiments of the disclosure have a same function of optimizing the electric field intensity distribution.

Please refer to FIG. 12, brightness of the structures illustrated in FIG. 1, FIG. 3, FIG. 8, FIG. 9 and FIG. 10 is tested under a same condition, specifically, an ordinate represents a percentage increase in brightness of each structure illustrated in FIG. 3, FIG. 8, FIG. 9 and FIG. 10 relative to FIG. 1. As shown in FIG. 12, the light-emitting brightness of the structures illustrated in FIG. 1 and FIG. 3 is much lower than that of the structures illustrated in FIG. 8, FIG. 9 and FIG. 10, which reflects from the side that the design of the first current blocking layer 40 in the embodiment of the disclosure has obvious brightness advantages, and the performance of the whole light-emitting diode is better.

It should be noted that a distribution form of the first current blocking layer 40 is not limited to the above descriptions, and adaptive changes made on the basis of it also belong to a scope of protection of the disclosure. Similarly, shapes and sizes of the first electrode 20 and the second electrode 30 can be designed according to actual structures and requirements of the light-emitting diode, each drawing is only a reference, and not limited here.

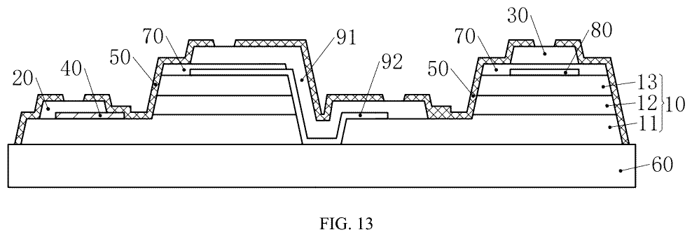

It should also be noted that the light-emitting diodes provided by the above embodiments are not only suitable for a chip with the forward-installed structure shown in FIG. 5 and a chip with the flip structure shown in FIG. 6, but also suitable for a chip with high voltage structure. As shown in FIG. 13, the chip with high voltage structure includes: multiple light-emitting units, a substrate 60 and an insulation layer 50, adjacent light-emitting units are isolated to each other through an isolation groove on the substrate 60, and an electrical connection between the adjacent light-emitting units is achieved through an interconnected electrode 91 spanning across the isolation groove. A third current blocking layer 92 is disposed below the interconnected electrode 91 to achieve the current blocking effect, and avoid the current accumulation phenomenon.

In an embodiment, each light-emitting unit includes: a semiconductor stacked layer 10, and the semiconductor stacked layer 10 includes: a first semiconductor layer 11, a light-emitting layer 12 and a second semiconductor layer 13 sequentially stacked in that order from bottom to top. Each light-emitting unit further includes: a first electrode 20 electrically connected to the first semiconductor layer 11 or a second electrode 30 electrically connected to the second semiconductor layer 13. Specifically, a bottom of the first electrode 20 is provided with a first current blocking layer 40 as described in the above embodiments. Furthermore, a bottom of the second electrode 30 can be also provided with a transparent current expansion layer 70 and a second current blocking layer 80 as described in the above embodiments. Specific structures, performances and advantages of the first electrode 20 and the second electrode 30 can refer to the aforementioned contents, and is not repeated here.

The disclosure further provides a light-emitting device, the light-emitting device includes: the light-emitting diode as described in the above embodiments, which can effectively improve performances of the light-emitting device.

In summary, the pattern of the first current blocking layer below the first electrode is designed by the light-emitting diode provided by the disclosure, which can effectively improve the phenomena of uneven electric field intensity distribution and current accumulation, so as to improve the light extraction ability and the resistance to ESD impact of the light-emitting diode.

Finally, it should be noted that the above embodiments are merely used to describe the technical solutions of the disclosure, and not to limit them. Although the disclosure is described in detail with reference to the aforementioned embodiments, those skilled in the art should understand that they can still modify the technical solutions recorded in the aforementioned embodiments, or equivalently replace some or all of the technical features. The modifications or replacements do not make an essence of the corresponding technical solutions deviate from the scope of the technical solutions of the various embodiments of the disclosure.

What is claimed is:

1. A light-emitting diode, comprising:
a semiconductor stacked layer, having lower and upper surfaces opposite to each other; wherein the semiconductor stacked layer comprises: a first semiconductor layer, a light-emitting layer and a second semiconductor layer sequentially stacked in that order from the lower surface to the upper surface;
a first electrode, disposed on the first semiconductor layer, and electrically connected to the first semiconductor layer;
a second electrode, disposed on the second semiconductor layer, and electrically connected to the second semiconductor layer; and
a first current blocking layer, disposed between the first semiconductor layer and the first electrode;
wherein the first current blocking layer comprises: a first blocking area and a second blocking area; the first blocking area overlaps with the first electrode and the second blocking area does not overlap with the first electrode as viewed in a direction from above the light-emitting diode towards the semiconductor stacked layer; and at least part of the second blocking area is disposed outside an edge of the first electrode proximate to a side of the second electrode.

2. The light-emitting diode as claimed in claim 1, wherein a shortest distance is defined between the edge of the first electrode and an edge of the second electrode, and at least part of the second blocking area is located between the edge of the first electrode and the edge of the second electrode with the shortest distance.

3. The light-emitting diode as claimed in claim 1, wherein the first electrode completely or partially overlaps with the first blocking area as viewed in the direction from above the light-emitting diode towards the semiconductor stacked layer.

4. The light-emitting diode as claimed in claim 3, wherein the first electrode partially overlaps with the first blocking area as viewed in the direction from above the light-emitting diode towards the semiconductor stacked layer, and a projection area of the first blocking area on the first semiconductor layer accounts for 5% to 96% of a projection area of the first electrode on the first semiconductor layer.

5. The light-emitting diode as claimed in claim 3, wherein the first electrode partially overlaps with the first blocking area as viewed in the direction from above the light-emitting diode towards the semiconductor stacked layer, and a projection area of the first blocking area on the first semiconductor layer accounts for 50% to 96% of a projection area of the first electrode on the first semiconductor layer.

6. The light-emitting diode as claimed in claim 3, wherein the first electrode partially overlaps with the first blocking area as viewed in the direction from above the light-emitting diode towards the semiconductor stacked layer, and a projection area of the first blocking area on the first semiconductor layer accounts for 10% to 95% of a projection area of the first current blocking layer on the first semiconductor layer.

7. The light-emitting diode as claimed in claim 4, wherein at least part of the first blocking area is disposed inside the edge of the first electrode proximate to the second electrode as viewed in the direction from above the light-emitting diode towards the semiconductor stacked layer.

8. The light-emitting diode as claimed in claim 3, wherein the first blocking area partially overlaps with the first electrode, the first electrode comprises: a non-overlapping electrode area not overlapping with the first blocking area, and at least part of the non-overlapping electrode area is disposed inside an edge of the first electrode facing away from the second electrode.

9. The light-emitting diode as claimed in claim 8, wherein a projection area of the non-overlapping electrode area on the first semiconductor layer accounts for 4% to 95% of a projection area of the first electrode on the first semiconductor layer.

10. The light-emitting diode as claimed in claim 8, wherein the first blocking area and the second blocking area extend to cover edge areas of the first electrode beyond the non-overlapping electrode area.

11. The light-emitting diode as claimed in claim 1, wherein the semiconductor stacked layer defines a mesa exposing a part of an upper surface of the first semiconductor layer, the first electrode is disposed on the mesa, and a projection of the second blocking area on the mesa is located inside the mesa.

12. The light-emitting diode as claimed in claim 11, wherein a minimum distance is defined between the projection of the second blocking area on the mesa and an edge of the mesa, and the minimum distance is larger than or equal to 1 micron (μm).

13. The light-emitting diode as claimed in claim 1, wherein a distance between the second blocking area and the edge of the first electrode is larger than or equal to 1 μm as viewed in the direction from above the light-emitting diode towards the semiconductor stacked layer.

14. The light-emitting diode as claimed in claim 1, wherein the first current blocking layer is in an annular shape, and an inner ring of the annular shape is located inside the first electrode as viewed in the direction from above the light-emitting diode towards the semiconductor stacked layer.

15. The light-emitting diode as claimed in claim 4, wherein a pattern of the first current blocking layer is consistent with that of the first electrode, and the pattern of the first current blocking layer is offset towards a direction proximate to the second electrode as viewed in the direction from above the light-emitting diode towards the semiconductor stacked layer.

16. The light-emitting diode as claimed in claim 1, wherein a material of the first current blocking layer is an insulating material that at least partially transmits light, the material of the first current blocking layer is at least one selected from the group consisting of silicon oxide, titanium oxide, silicon nitride, aluminum oxide, magnesium fluoride, spin-on glass and polymer, and a thickness of the first current blocking layer is in a range of 50 to 500 nanometers (nm).

17. The light-emitting diode as claimed in claim 1, wherein the light-emitting diode further comprises:
a transparent current expansion layer, disposed below the second electrode; and
a second current blocking layer, disposed below the second electrode, and disposed between the semiconductor stacked layer and the transparent current expansion layer; wherein a projection of the second electrode on the second current blocking layer is located inside the second current blocking layer.

18. The light-emitting diode as claimed in claim 1, wherein the light-emitting diode further comprises: an insulation layer, covering a side wall of the semiconductor stacked layer.

19. The light-emitting diode as claimed in claim 1, wherein a number of the semiconductor stacked layer is two, the first electrode is disposed on the first semiconductor layer of one of the two semiconductor stacked layers, and the second electrode is disposed on the second semiconductor layer of the other of the two semiconductor stacked layers;
the light-emitting diode further comprises:
a substrate; wherein the two semiconductor stacked layers are arranged on the substrate at intervals;
an interconnected electrode, disposed on the substrate, and electrically connected to the two semiconductor stacked layers; wherein the interconnected electrode is disposed between the first electrode and the second electrode; and
a third current blocking layer, disposed between the substrate and the interconnected electrode.

20. A light-emitting device, comprising: the light-emitting diode as claimed in claim 1.
